(19) United States
(12) Patent Application Publication
(10) Pub. No.: US 2010/0091215 A1
(43) Pub. Date: Apr. 15, 2010

(54) SEMICONDUCTOR LIGHT-EMITTING DEVICE AS WELL AS IMAGE DISPLAY AND LIQUID CRYSTAL DISPLAY EMPLOYING THE SAME

(76) Inventors: Hiroshi FUKUNAGA, Osaka-shi (JP); Kenichi YOSHIMURA, Osaka-shi (JP)

Correspondence Address: BIRCH STEWART KOLASCH & BIRCH, PO BOX 747, FALLS CHURCH, VA, 22040-0747, US

(21) Appl. No.: 12/571,999

(22) Filed: Oct. 1, 2009

(30) Foreign Application Priority Data
Oct. 9, 2008 (JP) 2008-263136(P)

(51) Int. Cl. G02F 1/1335; H01L 33/00; F21V 7/04

(52) U.S. Cl. 349/61; 257/98; 362/612; 257/E33.001

(57) ABSTRACT

The present invention relates to a semiconductor light-emitting device including a semiconductor light-emitting element emitting excitation light, a green phosphor and a red phosphor and including an Mn⁴⁺-activated phosphor as the red phosphor, as well as an image display and a liquid crystal display each employing the same. According to the present invention, a semiconductor light-emitting device capable of implementing a display showing deeper red than ever as well as an image display and a liquid crystal display each employing the same are provided.

This nonprovisional application is based on Japanese Patent Application No. 2008-263136 filed on Oct. 9, 2008 with the Japan Patent Office, the entire contents of which are hereby incorporated by reference.

### BACKGROUND OF THE INVENTION

1. Field of the Invention

The present invention relates to a semiconductor light-emitting device including a semiconductor light-emitting element and phosphors as well as an image display and a liquid crystal display each employing the same.

2. Description of the Background Art

The competition for developing a backlight for a miniature liquid crystal display (LCD) has recently been intensified. While various systems of backlight sources are proposed in this field, no system simultaneously satisfying brightness and color reproducibility (NTSC ratio) has not yet been found. The NTSC ratio denotes the ratio of the area of a triangle obtained by connecting the chromaticity coordinates (u′, v′) of red, green and blue on a CIE1976 chromaticity diagram to the area of a triangle obtained by connecting the chromaticity coordinates (u′, v′) ((0.498, 0.519), (0.076, 0.576) and (0.152, 0.196)) of red, green and blue on the CIE1976 chromaticity diagram set by NTSC (National Television System Committee).

At present, a light-emitting device emitting white light formed by combining a light-emitting element (peak wavelength: about 450 nm) emitting blue light and a wavelength transformation portion employing a trivalent cerium-activated (Y,Gd)₃(Al,Ga)₅O₁₂ phosphor or a bivalent europium-activated (Sr,Ba,Ca)₂SiO₄ phosphor excited by the blue light to emit yellow light is mainly employed as the backlight source for an LCD. When this light-emitting device is employed as the backlight for the LCD, however, color reproducibility (NTSC ratio) of the LC remains at about 70%.

For example, Japanese Patent Laying-Open No. 2004-287323 describes an RGB-LED formed by integrating a red LED chip, a green LED chip and a blue LED chip into a package and a structure obtained by combining an LED emitting ultraviolet light and an RGB phosphor with each other as backlights employing light-emitting diodes (LEDs). While the former can implement an NTSC ratio exceeding 100%, it is difficult to produce a desired color due to different driving characteristics of the LEDs, and the RGB-LED is unsuitable to a mobile device due to complicated driving circuits. The latter includes no blue phosphor having high brightness and suitable for a backlight.

Japanese Patent Laying-Open No. 2006-016413 discloses a light-emitting device emitting white light by exciting Eu-activated CaAlSiN₃ which is a nitride-based phosphor emitting red light and a phosphor emitting green light with a light-emitting element emitting blue light. According to this system, a blue LED can be used as the light-emitting element emitting blue light, and hence the aforementioned problem of the absence of the blue phosphor having high brightness and suitable for a backlight can be solved. An Eu-activated β-sialon phosphor according to Japanese Patent Laying-Open No. 2005-255895, for example, has generally been suitably used as the phosphor emitting green light. The phosphors described in Japanese Patent Laying-Open Nos. 2006-016413 and 2005-255895 are based on silicon nitride-based ceramics stable against chemical and mechanical shocks, and hence a light-emitting device superior in environmental resistance and excellent in color stability can be implemented with these phosphors. When the light-emitting device emitting white light is formed by combining the green and red phosphors with the blue LED, wider color reproducibility (NTSC ratio) can be implemented as compared with the aforementioned case of employing the trivalent cerium-activated (Y,Gd)₃(Al,Ga)₅O₁₂ phosphor or the bivalent europium-activated (Sr,Ba,Ca)₂SiO₄ phosphor emitting yellow light.

When the light-emitting device emitting white light with the blue LED and the red and green phosphors is employed as the backlight source of an image display such as a liquid crystal display, the color reproduction range of the display tends to widen if any of the phosphors has a small emission spectral width. When the blue LED and the phosphors described in Japanese Patent Laying-Open Nos. 2006-016413 and 2005-255895 are employed, the color reproduction range of red is insufficient since the red phosphor has an emission spectral width of at least 80 nm. Therefore, awaited are a semiconductor light-emitting device, emitting white light, capable of implementing a display showing deeper red and an image display employing the semiconductor light-emitting device emitting white light.

### SUMMARY OF TIM INVENTION

The present invention has been proposed in order to solve the aforementioned problems, and an object thereof is to provide a semiconductor light-emitting device capable of implementing a display capable of showing deeper red than ever with a semiconductor light-emitting element and phosphors and an image display employing the same.

The semiconductor light-emitting device according to the present invention includes a semiconductor light-emitting element emitting excitation light, a green phosphor and a red phosphor, and includes an Mn⁴⁺-activated phosphor as the red phosphor.

An Mn⁴⁺-activated phosphor having an emission peak wavelength of at least 625 nm and an emission spectral half width of not more than 30 nm can be suitably employed as the Mn⁴⁺-activated phosphor in the present invention.

The aforementioned Mn⁴⁺-activated phosphor is preferably Mn⁴⁺-activated Mg fluorogermanate or Mn⁴⁺-activated K₂MF₆ (M=Si, Ge or Ti).

A green phosphor having an emission peak wavelength of at least 510 nm and not more than 550 nm and an emission spectral half width of not more than 55 nm can be suitably employed as the green phosphor in the present invention.

An Eu-activated β-sialon phosphor or an Mn-activated γ-AlON phosphor can be suitably employed as the green phosphor in the present invention.

According to the present invention, the emission peak wavelength of the semiconductor light-emitting element is preferably 430 to 460 nm, more preferably 440 to 450 nm.

The present invention also provides an image display and a liquid display each including the aforementioned semiconductor light-emitting device emitting white light as a backlight source.

According to the present invention, a semiconductor light-emitting device capable of implementing a display capable of showing deeper red than ever when applied to an image display such as a liquid crystal display can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view schematically showing a semiconductor light-emitting device 1 according to a preferred example of the present invention;

FIG. 2 is an exploded perspective view schematically showing an image display 21 according to a preferred example of the present invention;

FIG. 3 is an exploded perspective view showing a liquid crystal display 24 shown in FIG. 2 in an enlarged manner;

FIG. 4 is a graph showing transmission spectra of blue, green and red color filters suitably used in the liquid crystal display according to the present invention, with transmittances (%) and wavelengths (nm) shown on the axes of ordinates and abscissas respectively;

FIG. 5 is a graph showing the absorption (excitation) spectrum of phosphor powder obtained according to preparation example 1, with luminous intensities (arbitrary unit) and wavelengths (nm) shown on the axes of ordinates and abscissas respectively;

FIG. 6 is a graph showing the emission spectrum of the phosphor powder obtained according to preparation example 1, with luminous intensities (arbitrary unit) and wavelengths (nm) shown on the axes of ordinates and abscissas respectively;

FIG. 7 is a graph showing the absorption (excitation) spectrum of phosphor powder obtained according to preparation example 2, with luminous intensities (arbitrary unit) and wavelengths (nm) shown on the axes of ordinates and abscissas respectively;

FIG. 8 is a graph showing the emission spectrum of the phosphor powder obtained according to preparation example 2, with luminous intensities (arbitrary unit) and wavelengths (nm) shown on the axes of ordinates and abscissas respectively;

FIG. 9 is a graph showing the emission spectrum of phosphor powder obtained according to comparative preparation example 1, with luminous intensities (arbitrary unit) and wavelengths (nm) shown on the axes of ordinates and abscissas respectively;

FIG. 10 is a graph showing the emission spectrum of phosphor powder obtained according to preparation example 3, with luminous intensities (arbitrary unit) and wavelengths (nm) shown on the axes of ordinates and abscissas respectively;

FIG. 11 is a graph showing the emission spectrum of phosphor powder obtained according to preparation example 4, with luminous intensities (arbitrary unit) and wavelengths (nm) shown on the axes of ordinates and abscissas respectively;

FIG. 12 is a graph showing the emission spectrum of phosphor powder obtained according to preparation example 5, with luminous intensities (arbitrary unit) and wavelengths (nm) shown on the axes of ordinates and abscissas respectively;

FIG. 13 is a graph showing the emission spectrum of a semiconductor light-emitting device 1 prepared according to Example 1, with luminous intensities (arbitrary unit) and wavelengths (nm) shown on the axes of ordinates and abscissas respectively;

FIG. 14 is a graph showing the emission spectrum of a semiconductor light-emitting device 1 prepared according to Example 3, with luminous intensities (arbitrary unit) and wavelengths (nm) shown on the axes of ordinates and abscissas respectively;

FIG. 15 is a graph showing the emission spectrum of a semiconductor light-emitting device 1 prepared according to Example 5, with luminous intensities (arbitrary unit) and wavelengths (nm) shown on the axes of ordinates and abscissas respectively;

FIG. 16 is a graph showing the emission spectrum of a semiconductor light-emitting device 1 prepared according to Example 7, with luminous intensities (arbitrary unit) and wavelengths (nm) shown on the axes of ordinates and abscissas respectively;

FIG. 17 is a graph showing the emission spectrum of a semiconductor light-emitting device 1 prepared according to Example 9, with luminous intensities (arbitrary unit) and wavelengths (nm) shown on the axes of ordinates and abscissas respectively;

FIG. 18 is a graph showing the emission spectrum of a semiconductor light-emitting device 1 prepared according to Example 11, with luminous intensities (arbitrary unit) and wavelengths (nm) shown on the axes of ordinates and abscissas respectively;

FIG. 19 is a graph showing the emission spectrum of a semiconductor light-emitting device 1 prepared according to comparative example 1, with luminous intensities (arbitrary unit) and wavelengths (nm) shown on the axes of ordinates and abscissas respectively;

FIG. 20 is a graph showing the emission spectrum of a semiconductor light-emitting device 1 prepared according to comparative example 3, with luminous intensities (arbitrary unit) and wavelengths (nm) shown on the axes of ordinates and abscissas respectively; and

FIG. 21 is a graph showing the emission spectrum of a semiconductor light-emitting device 1 prepared according to comparative example 5, with luminous intensities (arbitrary unit) and wavelengths (nm) shown on the axes of ordinates and abscissas respectively.

### DESCRIPTION OF THE PREFERRED EMBODIMENTS

### Semiconductor Light-Emitting Device

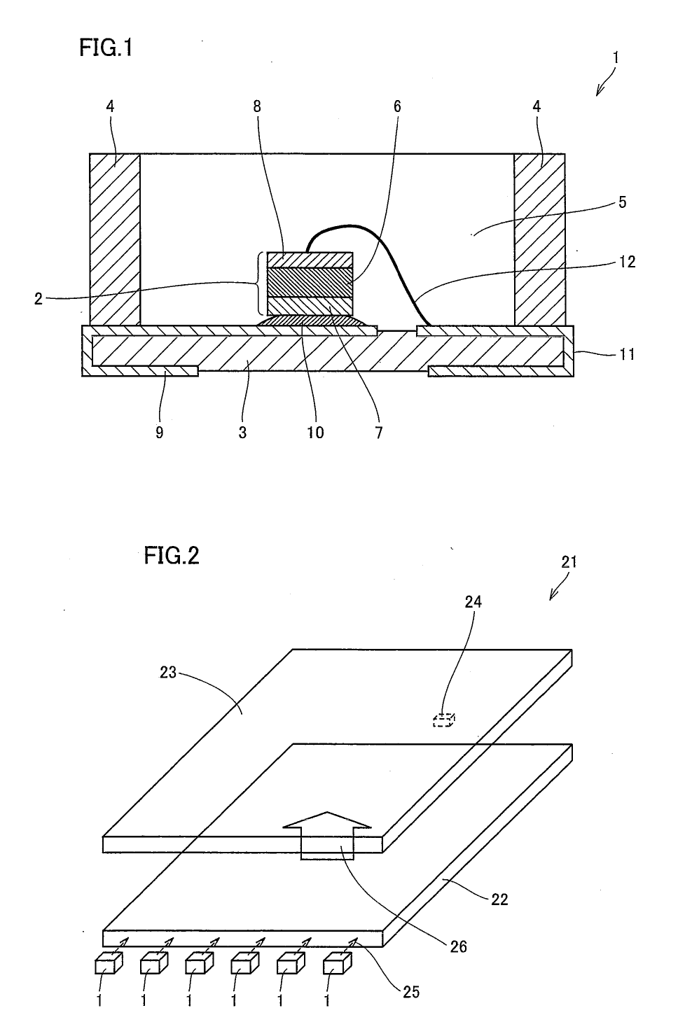

FIG. 1 is a sectional view showing a semiconductor light-emitting device 1 according to a preferred example of the present invention. Semiconductor light-emitting device 1 according to the present invention includes a semiconductor light-emitting element 2 emitting excitation light and an Mn⁴⁺-activated red phosphor (not shown) absorbing the excitation light and emitting red light. In semiconductor light-emitting device 1 according to the example shown in FIG. 1, semiconductor light-emitting element 2 is placed on a printed wiring board 3 serving as a base, and molding resin 5 made of translucent resin into which a phosphor is dispersed is charged into a resin frame 4 also placed on printed wiring board 3, to seal semiconductor light-emitting element 2. In the example shown in FIG. 1, semiconductor light-emitting element 2 has an InGaN layer 6 serving as an active layer as well as n- and p-side electrodes 7 and 8 formed on both sides of InGaN layer 6, while n-side electrode 7 is electrically connected to an n electrode portion 9 provided over the upper surface and the back surface of printed wiring board 3 through a conductive adhesive layer 10. In the example shown in FIG. 1, p-side electrode 8 of semiconductor light-emitting element 2 is electrically connected to a p electrode portion 11 provided over the upper surface and the back surface of printed wiring board 3 independently of n electrode portion 9 through a metal wire 12. The semiconductor light-emitting device according to the present invention is not restricted to the structure shown in FIG. 1, but a general structure well known in the art can be employed.

<Red Phosphor>

In the Mn⁴⁺-activated phosphor employed as the red phosphor in the semiconductor light-emitting device according to the present invention, the emission spectral peak wavelength thereof is preferably at least 625 nm, and the emission spectral half width thereof is preferably not more than 30 nm. When the emission spectral peak wavelength of the red phosphor is at least 625 nm and the emission spectral half width thereof is not more than 30 nm, the red phosphor emits red light in a deep region. When the red phosphor emits red light in a deep region, a display showing deep red can be implemented when the semiconductor light-emitting device according to the present invention is applied to an image display such as a liquid crystal display. An Mn⁴⁺-activated Mg fluorogermanate phosphor illustrated in William M. Yen and Marvin J. Weber, “INORGANIC PHOSPHORS”, p. 212 (4.10 Miscellaneous Oxides, SECTION 4: PHOSPHOR DATA) published by CRC Press or an Mn⁴⁺-activated K₂MF₆ (M=Si, Ge or Ti) phosphor illustrated in Journal of the Electrochemical Society: SOLID-STATE SCIENCE AND TECHNOLOGY, July 1973, p. 942 can be listed as a preferable specific example of such an Mn⁴⁺-activated phosphor. An Mn⁴⁺-activated phosphor having an emission peak wavelength of at least 625 nm and an emission spectral half width of not more than 30 nm is suitably employed as the Mn⁴⁺-activated phosphor.

The Mn⁴⁺-activated Mg fluorogermanate phosphor is efficiently excited by blue light of 400 to 460 nm, and has a sharp emission spectral half width of 15 nm and an emission peak wavelength of 659 nm. The Mn⁴⁺-activated Mg fluorogermanate phosphor exhibits deep red with an emission spectral chromaticity point of (u′, v′)=(0.569, 0.513) on a CIE1976 chromaticity diagram. The Mn⁴⁺-activated K₂MF₆ (M=Si, Ge or Ti) phosphor is efficiently excited by blue light of 400 to 460 nm, and has a sharp emission spectral half width of 8 nm and an emission peak wavelength of 631 nm. The Mn⁴⁺-activated K₂MF₆ (M=Si, Ge or Ti) phosphor exhibits deep red with an emission spectral chromaticity point of (u′, v′)=(0.535, 0.520) on the CIE1976 chromaticity diagram. FIG. 4 is a graph showing transmission spectra of blue, green and red color filters suitably used in an image display according to the present invention described later, with transmittances (%) and wavelengths (nm) shown on the axes of ordinates and abscissas respectively. The Mn⁴⁺-activated Mg fluorogermanate phosphor or the Mn⁴⁺-activated K₂MF₆ (M=Si, Ge or Ti) phosphor employed in the present invention has excellent wavelength consistency with a red color filter, exhibiting the transmittance shown in FIG. 4, generally employed for a liquid crystal display. When employed as a backlight for an image display, therefore, the semiconductor light-emitting device according to the present invention can emit red light with high efficiency. The aforementioned emission characteristics indicate deeper red as compared with values (a half width of about 96 nm, an emission peak of about 650 nm and chromaticity coordinates ((u′, v′)≈(nearly equal) (0.443, 0.534)) exhibited by the emission spectrum of an Eu-activated CaAlSiN₃ phosphor employed for a conventional semiconductor light-emitting device. A deep color denotes a color whose color reproduction range is widened when an image display is constituted.

<Green Phosphor>

When the aforementioned Mn⁴⁺-activated phosphor is regarded a first phosphor, semiconductor light-emitting device 1 according to the present invention preferably further includes a second phosphor emitting green light upon irradiation with the excitation light. In other words, while semiconductor light-emitting element 2 emits blue light and the aforementioned Mn⁴⁺-activated phosphor emits red light in semiconductor light-emitting device 1 according to the present invention, a green phosphor is preferably employed as the second phosphor, in order to obtain semiconductor light-emitting device 1 emitting white light by mixing the blue light and the red light. In semiconductor light-emitting device 1 according to the example shown in FIG. 1, the second phosphor (not shown) is dispersed into molding resin 5 along with the aforementioned Mn⁴⁺-activated phosphor.

The second phosphor employed for semiconductor light-emitting device 1 according to the present invention is preferably formed by a green phosphor emitting green light having a peak wavelength in the wave range of 510 to 550 nm upon irradiation with the excitation light. If the peak wavelength of the second phosphor is out of the aforementioned range, wavelength consistency with the color filters shown in FIG. 4 is so deteriorated that not only the brightness of the image display employing the semiconductor light-emitting device is reduced but also the spectrum may overlap with that of the excitation light or the light emitted by the red phosphor to narrow the green color reproduction range.

According to the present invention, the emission spectral half width of the second phosphor is preferably not more than 55 nm, more preferably not more than 45 nm, so that the image display shows deeper green when the semiconductor light-emitting device is applied to the image display.

An Eu-activated β-sialon phosphor or an Mn-activated γ-AlON phosphor shown in the pamphlet of International Patent Laying-Open No. 2007/099862 and Summaries of 68^{th} Scientific Lectures of the Japan Society of Applied Physics, p. 1473, “Emission Characteristics of Aluminum Oxynitride Green Phosphor” can be suitably employed as such a second phosphor (green phosphor). Further, an Eu-activated β-sialon phosphor having a smaller emission spectral half width and a shorter peak wavelength shown in International Patent Laying-Open No. 2007/066733 can be more suitably employed.

When the aforementioned Eu-activated β-sialon phosphor and the Eu-activated CaAlSiN₃ phosphor described in Japanese Patent Laying-Open No. 2006-016413 employed as the red phosphor are combined with each other to constitute the light-emitting device, the emission spectra of the green phosphor and the red phosphor so remarkably overlap with each other that the color reproduction range is narrowed when the light-emitting device is applied to an image display. According to the present invention, however, the Mn⁴⁺-activated phosphor such as the Mn⁴⁺-activated Mg fluorogermanate phosphor or the Mn⁴⁺-activated K₂MF₆ (M=Si, Ge or Ti) phosphor is employed as the red phosphor, whereby the problem of the overlap between the spectra of the red and green phosphors can be solved. This is because the emission spectral half width of the red phosphor employed in the present invention is narrower as compared with the Eu-activated CaAlSiN₃ phosphor.

On the other hand, the fluorescent life times of the aforementioned Mn-activated γ-AlON phosphor and the Mn⁴⁺-activated phosphor employed as the red phosphor in the present invention were measured. As a result, the fluorescent life times of the Mn-activated γ-AlON phosphor and the Mn⁴⁺-activated phosphor, particularly the Mn⁴⁺-activated Mg fluorogermanate phosphor, were 4 msec. and 3 msec. respectively, and the afterglow times of the Mn-activated γ-AlON phosphor and the Mn⁴⁺-activated phosphor were at the same order. When an image display is prepared with the Mn-activated γ-AlON phosphor and the Mn⁴⁺-activated phosphor, therefore, influence exerted by the afterglow time on images can be easily controlled.

<Molding Resin>

In semiconductor light-emitting device 1 according to the present invention, molding resin 5 employed for sealing semiconductor light-emitting element 2 is prepared by dispersing a phosphor into translucent resin such as silicone resin or epoxy resin, and this phosphor includes the Mn⁴⁺-activated phosphor which is the aforementioned red phosphor (and the second phosphor (green phosphor) as the case may be). In this case, a phosphor mixture containing the green phosphor in addition to the red phosphor can be suitably employed as the dispersed phosphor, and a blue phosphor may be further added thereto if necessary. The mixing ratio of the dispersed phosphor is not particularly restricted but properly decided so that a spectrum exhibiting a desired white point is obtained on a screen when semiconductor light-emitting device 1 is applied to an image display and the color filters are fully opened, for example.

<Semiconductor Light-Emitting Element>

Semiconductor light-emitting element 2 employed for semiconductor light-emitting device 1 according to the present invention, which can be prepared from a semiconductor light-emitting element well known in the art, preferably emits primary light having an emission peak wavelength of 430 to 460 nm. If the emission peak wavelength of semiconductor light-emitting element 2 is out of the aforementioned range, the luminous efficiency of the red phosphor is reduced when the Mn⁴⁺-activated Mg fluorogermanate phosphor or the Mn⁴⁺-activated K₂MF₆ (M=Si, Ge or Ti) phosphor is employed as the Mn⁴⁺-activated phosphor, for example. A semiconductor light-emitting layer having an InGaN layer as an active layer can be preferably listed as a semiconductor light-emitting element exhibiting such an emission peak wavelength. The emission peak wavelength of semiconductor light-emitting element 2 employed in the present invention is more preferably 440 to 450 nm, to attain excellent wavelength consistency with a blue color filter described later.

<Printed Wiring Board>

A heat-resistant glass epoxy film or an insulating film can be employed as printed wiring board 3 employed in semiconductor light-emitting device 1 according to the present invention.

<p-Side Electrode>

A material such as Pd/Au, ITO (indium-tin oxide) or Ni can be employed from the side of active layer 6 as the structure of p-side electrode 8.

<n-Side Electrode>

Hf/Al, Ti/Al, Ti/Mo or Hf/Au can be employed from the side of active layer 6 as the structure of n-side electrode 7.

<n Electrode Portion>

Al or the like can be employed for n electrode portion 9.

<Image Display>

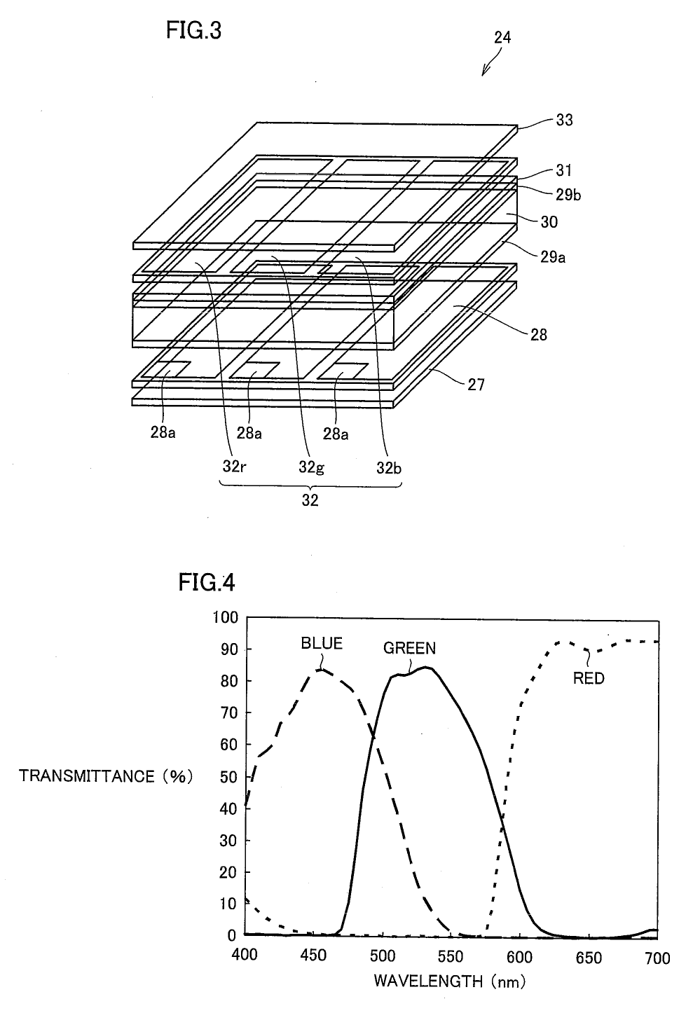

The present invention also provides an image display employing the aforementioned semiconductor light-emitting device according to the present invention emitting white light as a backlight source. FIG. 2 is an exploded perspective view schematically showing an image display 21 according to a preferred example of the present invention, and FIG. 3 is an exploded perspective view showing a liquid crystal display 24 shown in FIG. 2 in an enlarged manner. In image display 21 according to the example shown in FIG. 2, a plurality of (more specifically, six) semiconductor light-emitting devices 1 according to the example shown in FIG. 1 are arranged on a side surface of a transparent or semitransparent light guide 22. In the example shown in FIG. 2, semiconductor light-emitting devices 1 employ phosphors according to the present invention and phosphors emitting green light. In image display 21 according to the example shown in FIG. 2, a liquid crystal display portion 23 constituted of a plurality of liquid crystal displays 24 is provided adjacently to light guide 22, so that light 25 emitted from semiconductor light-emitting devices 1 is scattered in light guide 22 and applied to the overall surface of liquid crystal display portion 23 as scattered light 26.

<Liquid Crystal Display>

As shown in FIG. 3, each liquid crystal display 24 constituting liquid crystal display portion 23 is formed by successively stacking a polarizing plate 27, a transparent conductive film 28 (having thin-film transistors 28a), an orientation film 29b, a liquid crystal layer 30, another orientation film 29b, an upper thin-film electrode 31, a color filter 32 for displaying color pixels and an upper polarizing plate 33. Color filter 32 is divided into portions having sizes corresponding to respective pixels of transparent conductive film 28, and constituted of a red color filter 32r transmitting red light, a green color filter 32g transmitting green light and a blue color filter 32b transmitting blue light.

As shown in FIG. 3, liquid crystal display 24 according to the present invention preferably includes filters transmitting red light, green light and blue light respectively. In this case, general color filters exhibiting the transmission spectra shown in FIG. 4 can be suitably employed.

### EXAMPLES

While the present invention is now described in more detail with reference to Examples and comparative examples, the present invention is not restricted to these.

### [1] Preparation of Phosphor

### Preparation Example 1

### Preparation of Mn⁴⁺-Activated Mg Fluorogermanate Phosphor

A powder aggregate having a composition of 50.884 mass % of magnesium oxide powder, 11.187 mass % of magnesium fluoride powder, 1.660 mass % of magnesium carbonate powder and 36.269 mass % of germanium oxide powder was obtained by weighing prescribed quantities of these materials and mixing the materials with each other for at least 10 minutes with a mortar and a pestle of silicon nitride sintered bodies. This powder aggregate was introduced into a crucible of boron nitride having a diameter of 20 mm and a height of 20 mm by gravity-drop, and the crucible was covered with a lid of boron nitride. Then, the crucible was set in a pressurized electric furnace of a graphite resistance heating system, heated to a temperature of 1200° C. and held at 1200° C. for 2 hours, to obtain a phosphor sample. The obtained phosphor sample was pulverized with a pestle of agate, to obtain phosphor powder. Then, the phosphor powder was reheated. The phosphor powder was introduced into the crucible of boron nitride having the diameter of 20 mm and the height of 20 mm by gravity-drop. Then, the crucible was set in the electric furnace of the graphite resistance heating system, heated to 1200° C. and held at the temperature for 16 hours, to obtain a phosphor sample. The obtained phosphor sample was pulverized with the pestle of agate, to obtain phosphor powder. When the phosphor powder was subjected to powder X-ray diffraction measurement (XRD) with Kα rays of Cu, all charts obtained from the phosphor powder exhibited an Mn⁴⁺-activated Mg fluorogermanate structure. The phosphor powder was irradiated with light having a wavelength of 365 nm emitted from a lamp, to confirm that the same emitted red light.

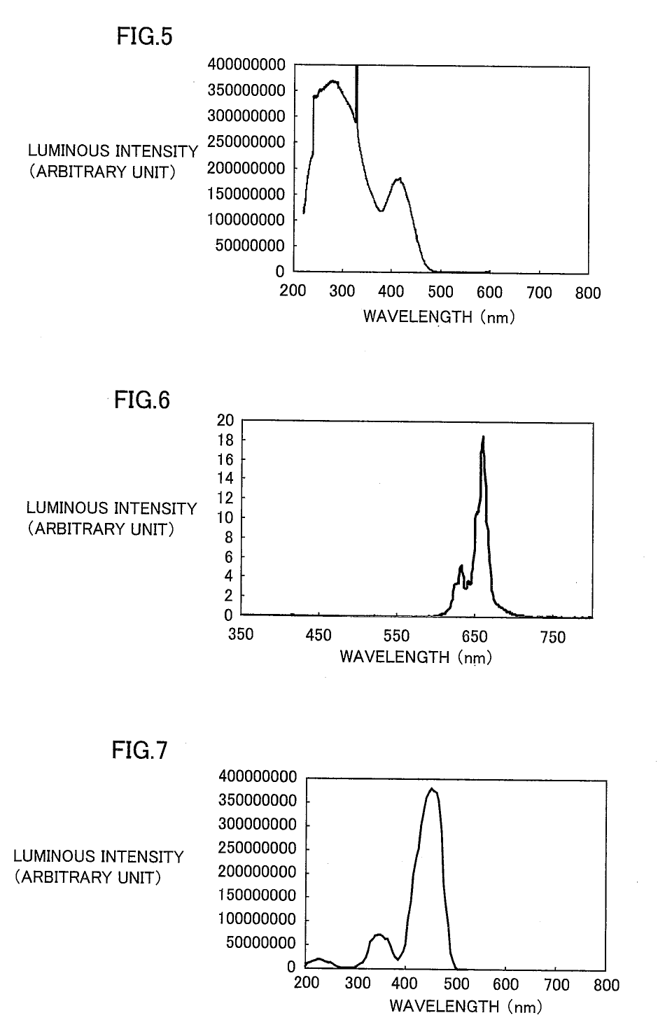

FIGS. 5 and 6 are graphs showing the absorption (excitation) spectrum (FIG. 5) and the emission spectrum (FIG. 6) of the obtained phosphor powder respectively, with luminous intensities (arbitrary unit) and wavelengths (nm) shown on the axes of ordinates and abscissas respectively. The absorption (excitation) spectrum and the emission spectrum of the phosphor powder shown in FIGS. 5 and 6 were measured with F-4500 (by Hitachi, Ltd.). The absorption (excitation) spectrum was measured by scanning the intensity at the emission peak of 657 nm. The emission spectrum was measured by exciting the phosphor powder with light of 450 nm. It is understood from FIG. 5 that the phosphor prepared according to preparation example 1 is efficiently excited with light in the range of 400 to 430 nm and exhibits particularly high excitation efficiency in the range of 412 to 422 nm. Further, it is understood from FIG. 6 that the emission spectrum of the phosphor prepared according to preparation example 1 has excellent wavelength consistency with the red color filter having the transmittance shown in FIG. 4. The chromaticity coordinates, the peak wavelength and the half width of the emission spectrum shown in FIG. 6 were (u′, v′)=(0.569, 0.513), 657 nm and 16 nm respectively. The phosphor according to preparation example 1 was excited with the light of 450 nm, in consideration of excellent wavelength consistency with a blue color filter.

### Preparation Example 2

### Preparation of Mn⁴⁺-Activated K₂SiF₆ Phosphor

An n-type Si substrate was dipped in a solution of KMnO₄:H₂O:HF=3 g:50 cc:50 cc for 10 minutes, to obtain a crystal on the surface of the n-type Si substrate. Phosphor powder was obtained by separating the obtained crystal from the Si substrate, washing and filtrating the same. When the phosphor powder was subjected to powder X-ray diffraction measurement (XRD) with Kα rays of Cu, all charts obtained from the phosphor powder exhibited an Mn⁴⁺-activated K₂SiF₆ structure. The phosphor powder was irradiated with light having a wavelength of 365 nm emitted from a lamp, to confirm that the same emitted red light.

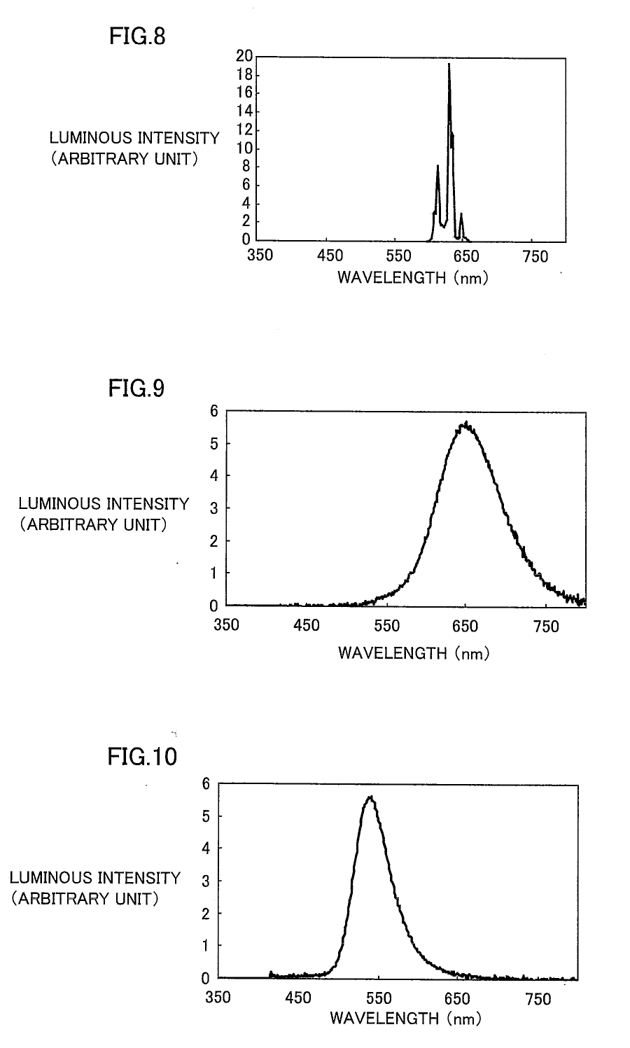

FIGS. 7 and 8 are graphs showing the absorption (excitation) spectrum (FIG. 7) and the emission spectrum (FIG. 8) of the obtained phosphor powder respectively, with luminous intensities (arbitrary unit) and wavelengths (nm) shown on the axes of ordinates and abscissas respectively. The absorption (excitation) spectrum and the emission spectrum of the phosphor powder shown in FIGS. 7 and 8 were measured with F-4500 (by Hitachi, Ltd.). The absorption (excitation) spectrum was measured by scanning the intensity at the emission peak of 631 nm. The emission spectrum was measured by exciting the phosphor powder with light of 450 nm. It is understood from FIG. 7 that the phosphor prepared according to preparation example 2 is efficiently excited with light in the range of 430 to 460 nm and exhibits particularly high excitation efficiency in the range of 445 to 455 nm. Further, it is understood from FIG. 8 that the emission spectrum of the phosphor prepared according to preparation example 2 has excellent wavelength consistency with the red color filter having the transmittance shown in FIG. 4. The chromaticity coordinates, the peak wavelength and the half width of the emission spectrum shown in FIG. 8 were (u′, v′)=(0.535, 0.520), 631 nm and 8 nm respectively. The phosphor according to preparation example 2 was excited with the light of 450 nm, in consideration of excellent wavelength consistency with a blue color filter.

### Preparation Example 3

### Preparation 1 of E-Activated β-Sialon Phosphor

A powder aggregate having a composition of 95.82 mass % of α-type silicon nitride powder, 3.37 mass % of aluminum nitride powder and 0.81 mass % of europium oxide powder was obtained by weighing prescribed quantities of these materials and mixing the materials with each other for at least 10 minutes with a mortar and a pestle of silicon nitride sintered bodies. This powder aggregate was introduced into a crucible of boron nitride having a diameter of 20 mm and a height of 20 mm by gravity-drop.

Then, the crucible was set in a pressurized electric furnace of a graphite resistance heating system, into which nitrogen having purity of 99.999 volume % was introduced to set the pressure to 1 MPa, thereafter heated at 500° C. per hour up to 1900° C. and held at the temperature for 8 hours, to obtain a phosphor sample. The obtained phosphor sample was pulverized with a mortar of agate, to obtain phosphor powder. When the phosphor powder was subjected to powder X-ray diffraction measurement (XRD) with Kα rays of Cu, all charts obtained from the phosphor powder exhibited a β-sialon structure. The phosphor powder was irradiated with light having a wavelength of 365 nm emitted from a lamp, to confirm that the same emitted green light.

FIG. 10 is a graph showing the emission spectrum of the obtained phosphor powder, with luminous intensities (arbitrary unit) and wavelengths (nm) shown on the axes of ordinates and abscissas respectively. The emission spectrum of the phosphor powder shown in FIG. 10 was also measured with F-4500 (by Hitachi, Ltd.). The emission spectrum shown in FIG. 10 was measured by exciting the phosphor powder with light of 450 nm. The chromaticity coordinates, the peak wavelength and the half width of the emission spectrum shown in FIG. 10 were (u′, v′)=(0.118, 0.573), 540 nm and 55 nm respectively.

### Preparation Example 4

### Preparation 2 of Eu-Activated β-Sialon Phosphor

A powder aggregate, excellent in fluidity, having a composition of 95.20 mass % of silicon powder passed through a sieve of 45 μm, 4.55 mass % of aluminum nitride powder and 0.26 mass % of europium oxide powder was obtained by weighing prescribed quantities of these materials, mixing the materials with each other for at least 10 minutes with a mortar and a pestle of silicon nitride sintered bodies and thereafter passing the mixture through a sieve of 250 μm. This powder aggregate was introduced into a crucible of boron nitride having a diameter of 20 mm and a height of 20 mm by gravity-drop. Then, the crucible was set in an electric furnace of a graphite resistance heating system, into which nitrogen having purity of 99.999 volume % was introduced to set the pressure to 0.5 MPa, thereafter heated at 500° C. per hour up to 1300° C., thereafter heated at 1° C. per minute up to 1600° C. and held at the temperature for 8 hours, to obtain a phosphor sample. The obtained phosphor sample was pulverized with a mortar of agate, to obtain phosphor powder. The phosphor powder was subjected to powder X-ray diffraction measurement (XRD) with Kα rays of Cu. Consequently, all charts obtained from the phosphor powder exhibited a β-sialon structure. Then, the powder was reheated. The powder fired at 1600° C. was pulverized with the mortar and the pestle of silicon nitride sintered bodies, and thereafter introduced into the crucible of boron nitride having the diameter of 20 mm and the height of 20 mm by gravity-drop. Then, the crucible was set in the electric furnace of the graphite resistance heating system, into which nitrogen having purity of 99.999 volume % was introduced to set the pressure to 1 MPa, thereafter heated at 500° C. per hour up to 1900° C. and held at the temperature for 8 hours, to obtain a phosphor sample. The obtained phosphor sample was pulverized with the mortar of agate, to obtain phosphor powder. When the phosphor powder was subjected to powder X-ray diffraction measurement (XRD) with Kα rays of Cu, it was recognized that the phosphor powder had a β-sialon structure. The phosphor powder was irradiated with light having a wavelength of 365 nm emitted from a lamp, to confirm that the same emitted green light.

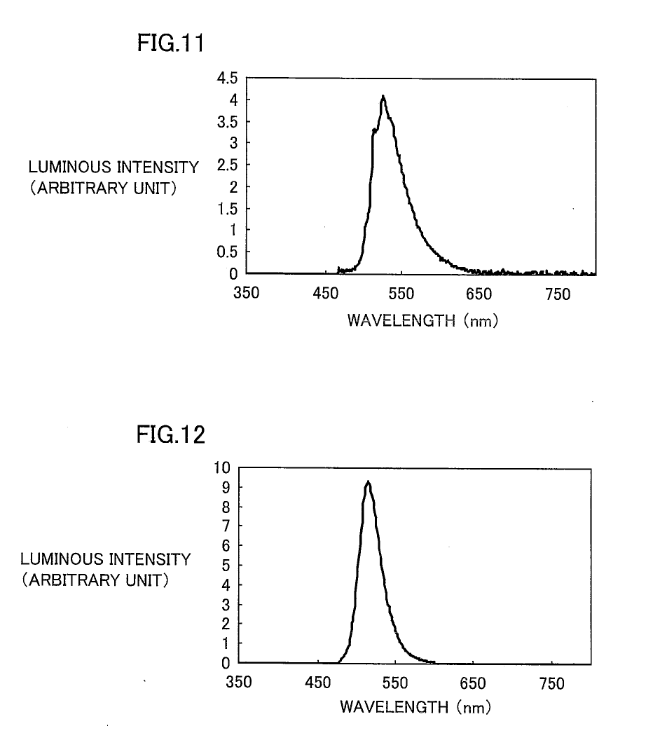

FIG. 11 is a graph showing the emission spectrum of the obtained phosphor powder, with luminous intensities (arbitrary unit) and wavelengths (nm) shown on the axes of ordinates and abscissas respectively. The emission spectrum of the phosphor powder shown in FIG. 11 was also measured with F-4500 (by Hitachi, Ltd.). The emission spectrum shown in FIG. 11 was measured by exciting the phosphor powder with light of 450 nm. The chromaticity coordinates, the peak wavelength and the half width of the emission spectrum shown in FIG. 11 were (u′, v′)=(0.093, 0.576), 524 nm and 44 nm respectively, and it is understood that the β-sialon phosphor according to preparation example 4 shows deeper green as compared with the β-sialon phosphor according to preparation example 3.

### Preparation Example 5

### Preparation of Mn-Activated γ-AlON Phosphor

In order to synthesize a material consisting of Al₇O₉N containing 1 mol % of Mn, which is AlON of a theoretical composition, a powder aggregate having a composition of 13.2 mass % of aluminum nitride powder, 85.3 mass % of aluminum oxide powder and 1.5 mass % of manganese carbonate powder was obtained by weighing prescribed quantities of these materials and mixing the materials with each other for at least 10 minutes with a mortar and a pestle of silicon nitride sintered bodies. This powder aggregate was introduced into a crucible of boron nitride having a diameter of 20 mm and a height of 20 mm by gravity-drop.

Then, the crucible was set in a pressurized electric furnace of a graphite resistance heating system, into which nitrogen having purity of 99.999 volume % was introduced to set the pressure to 0.5 MPa, thereafter heated at 500° C. per hour up to 1800° C. and held at the temperature for 2 hours, to obtain a phosphor sample. The obtained phosphor sample was pulverized with a mortar of agate, to obtain phosphor powder. When the phosphor powder was subjected to powder X-ray diffraction measurement (XRD) with Kα rays of Cu, all charts obtained from the phosphor powder exhibited a γ-AlON structure. The phosphor powder was irradiated with light having a wavelength of 365 nm emitted from a lamp, to confirm that the same emitted green light.

FIG. 12 is a graph showing the emission spectrum of the obtained phosphor powder, with luminous intensities (arbitrary unit) and wavelengths (nm) shown on the axes of ordinates and abscissas respectively. The emission spectrum of the phosphor powder shown in FIG. 12 was also measured with F-4500 (by Hitachi, Ltd.). The emission spectrum shown in FIG. 12 was measured by exciting the phosphor powder with light of 450 nm. The chromaticity coordinates, the peak wavelength and the half width of the emission spectrum shown in FIG. 12 were (u′, v′)=(0.042, 0.570), 515 nm and 33 nm respectively.

### Comparative Preparation Example 1

### Preparation of Eu-Activated CaAlSiN₃ (CASN) Phosphor

A powder aggregate having a composition of 29.741 mass % of aluminum nitride powder, 33.925 mass % of α-type silicon nitride powder, 35.642 mass % of calcium nitride powder and 0.692 mass % of europium nitride powder was obtained by weighing prescribed quantities of these materials and mixing the materials with each other for at least 10 minutes with a mortar and a pestle of silicon nitride sintered bodies. Europium nitride was synthesized by nitriding metal europium in ammonia. The powder aggregate was introduced into a crucible of boron nitride having a diameter of 20 mm and a height of 20 mm by gravity-drop. All of the steps of weighing the materials, mixing the same with each other and molding the mixture were carried out in a glove box capable of maintaining a nitrogen atmosphere having a moisture content of not more than 1 ppm and an oxygen content of not more than 1 ppm.

Then, the crucible was set in a pressurized electric furnace of a graphite resistance heating system, into which nitrogen having purity of 99.999 volume % was introduced to set the pressure to 1 MPa, thereafter heated at 500° C. per hour up to 1800° C. and held at 1800° C. for 2 hours to obtain phosphor powder. When the phosphor powder was subjected to powder X-ray diffraction measurement (XRD) with Kα rays of Cu, it was recognized that the phosphor powder had the structure of a CaAlSiN₃ crystal. The phosphor powder was irradiated with light having a wavelength of 365 nm emitted from a lamp, to confirm that the same emitted red light.

FIG. 9 is a graph showing the emission spectrum of the obtained phosphor powder, with luminous intensities (arbitrary unit) and wavelengths (nm) shown on the axes of ordinates and abscissas respectively. The emission spectrum of the phosphor powder shown in FIG. 9 was also measured with F-4500 (by Hitachi, Ltd.). The emission spectrum shown in FIG. 9 was measured by exciting the phosphor powder with light of 450 nm. The chromaticity coordinates, the peak wavelength and the half width of the emission spectrum shown in FIG. 9 were (u′, v′)=(0.443, 0.534), 650 nm and 96 nm respectively.

### [2] Preparation of Semiconductor Light-Emitting Device and Image Display

### Example 1

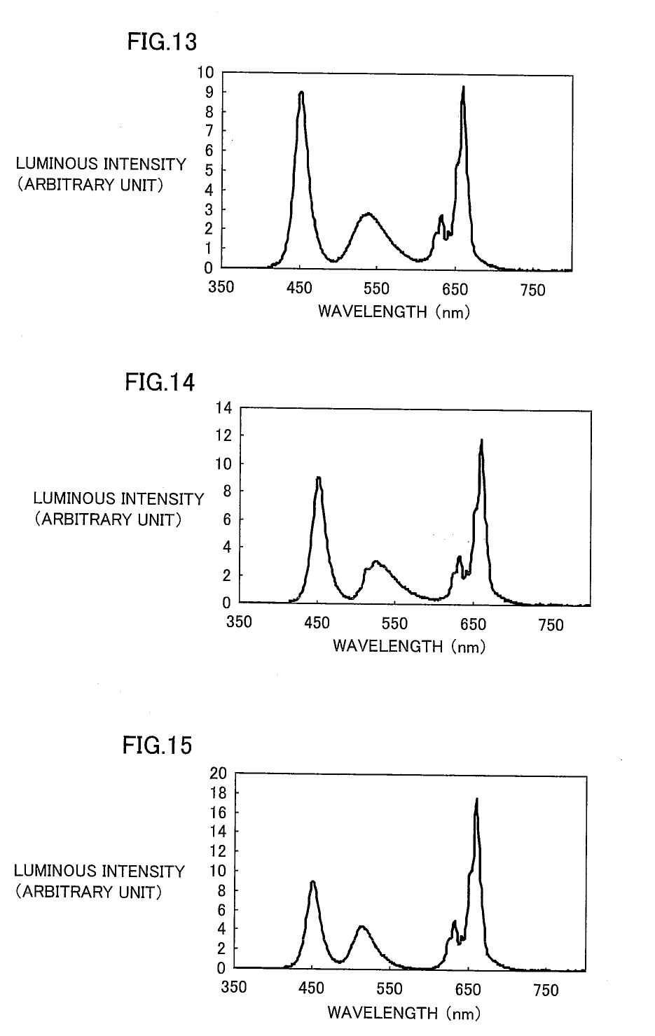

A semiconductor light-emitting device 1 having the structure shown in FIG. 1 was prepared. As a phosphor dispersed into molding resin 5, a phosphor mixture was obtained by mixing the Mn⁴⁺-activated Mg fluorogermanate phosphor according to preparation example 1 and the Eu-activated β-sialon phosphor according to preparation example 3 with each other at a weight ratio of 1:0.996. This phosphor mixture was mixed with silicone resin at a weight ratio of 1:20 and dispersed into the silicone resin, to obtain a molding resin component. An LED having an emission peak wavelength of 450 nm was employed as a semiconductor light-emitting element 2. FIG. 13 is a graph showing the emission spectrum of semiconductor light-emitting device 1 prepared according to Example 1, with luminous intensities (arbitrary unit) and wavelengths (nm) shown on the axes of ordinates and abscissas respectively. The emission spectrum shown in FIG. 13 was measured with MCPD-2000 (by Otsuka Electronics Co., Ltd.), and adjusted to show a white point around a color temperature of 10,000 K when constituting an image display having a structure according to Example 2 described below.

### Example 2

An image display having the structure shown in FIG. 2 was prepared. Semiconductor light-emitting device 1 according to Example 1 was employed as a backlight source, and a color filter exhibiting the transmittance shown in FIG. 4 was employed.

### Example 3

A semiconductor light-emitting device 1 having the structure shown in FIG. 1 was prepared. A phosphor mixture emitting white light obtained by mixing the Mn⁴⁺-activated Mg fluorogermanate phosphor according to preparation example 1 and the Eu-activated β-sialon phosphor according to preparation example 4 with each other at a weight ratio of 1:1.175 was employed as a phosphor dispersed into molding resin 5. This phosphor mixture was dispersed into silicone resin to be at a weight ratio of 1:14.389, to obtain a molding resin component. An LED having an emission peak wavelength of 450 nm was employed as a semiconductor light-emitting element 2. FIG. 14 is a graph showing the emission spectrum of semiconductor light-emitting device 1 prepared according to Example 3, with luminous intensities (arbitrary unit) and wavelengths (nm) shown on the axes of ordinates and abscissas respectively. The emission spectrum shown in FIG. 14 was measured with MCPD-2000 (by Otsuka Electronics Co., Ltd.), and adjusted to show a white point around a color temperature of 10,000 K when constituting an image display having a structure according to Example 4 described below.

### Example 4

An image display having the structure shown in FIG. 2 was prepared. Semiconductor light-emitting device 1 according to Example 3 was employed as a backlight source, and a color filter exhibiting the transmittance shown in FIG. 4 was employed.

### Example 5

A semiconductor light-emitting device 1 having the structure shown in FIG. 1 was prepared. A phosphor mixture emitting white light obtained by mixing the Mn⁴⁺-activated Mg fluorogermanate phosphor according to preparation example 1 and the Mn-activated γ-AlON phosphor according to preparation example 5 with each other at a weight ratio of 1:0.495 was employed as a phosphor dispersed into molding resin 5. This phosphor mixture was dispersed into silicone resin to be at a weight ratio of 1:14.184, to obtain a molding resin component. An LED having an emission peak wavelength of 450 nm was employed as a semiconductor light-emitting element 2. FIG. 15 is a graph showing the emission spectrum of semiconductor light-emitting device 1 prepared according to Example 5, with luminous intensities (arbitrary unit) and wavelengths (nm) shown on the axes of ordinates and abscissas respectively. The emission spectrum shown in FIG. 15 was measured with MCPD-2000 (by Otsuka Electronics Co., Ltd.), and adjusted to show a white point around a color temperature of 10,000 K when constituting an image display having a structure according to Example 6 described below.

### Example 6

An image display having the structure shown in FIG. 2 was prepared. Semiconductor light-emitting device 1 according to Example 5 was employed as a backlight source, and a color filter exhibiting the transmittance shown in FIG. 4 was employed.

### Example 7

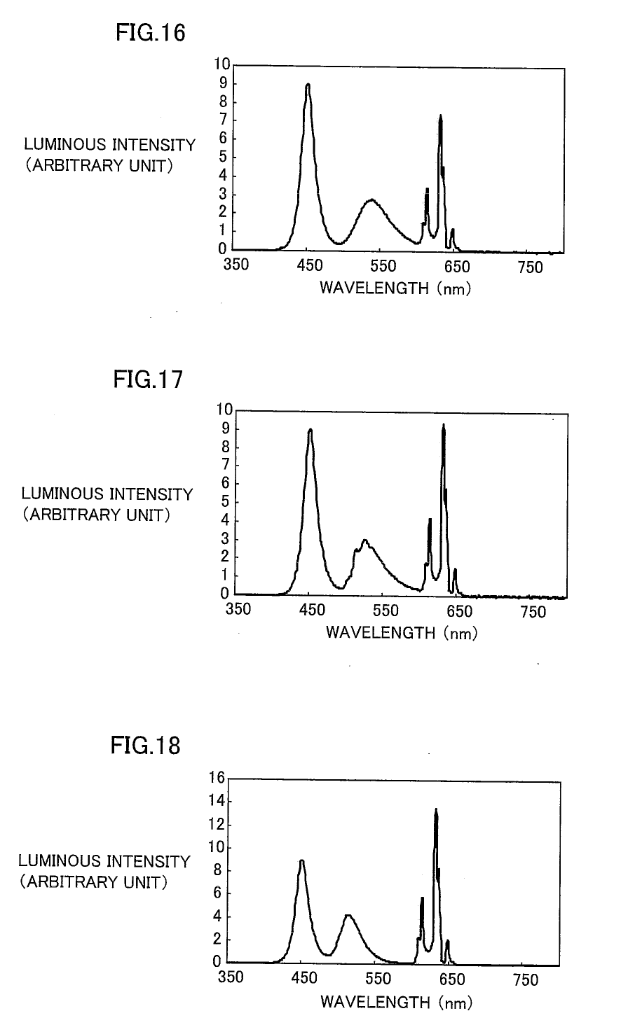

A semiconductor light-emitting device 1 having the structure shown in FIG. 1 was prepared. As a phosphor dispersed into molding resin 5, a phosphor mixture was obtained by mixing the Mn⁴⁺-activated K₂SiF₆ phosphor according to preparation example 2 and the Eu-activated β-sialon phosphor according to preparation example 3 with each other at a weight ratio of 1:2.603. This phosphor mixture was mixed with silicone resin at a weight ratio of 1:29.369 and dispersed into the silicone resin, to obtain a molding resin component. An LED having an emission peak wavelength of 450 nm was employed as a semiconductor light-emitting element 2. FIG. 16 is a graph showing the emission spectrum of semiconductor light-emitting device 1 prepared according to Example 7, with luminous intensities (arbitrary unit) and wavelengths (nm) shown on the axes of ordinates and abscissas respectively. The emission spectrum shown in FIG. 16 was measured with MCPD-2000 (by Otsuka Electronics Co., Ltd.), and adjusted to show a white point around a color temperature of 10,000 K when constituting an image display having a structure according to Example 8 described below.

### Example 8

An image display having the structure shown in FIG. 2 was prepared. Semiconductor light-emitting device 1 according to Example 7 was employed as a backlight source, and a color filter exhibiting the transmittance shown in FIG. 4 was employed.

### Example 9

A semiconductor light-emitting device 1 having the structure shown in FIG. 1 was prepared. As a phosphor dispersed into molding resin 5, a phosphor mixture was obtained by mixing the Mn⁴⁺-activated K₂SiF₆ phosphor according to preparation example 2 and the Eu-activated β-sialon phosphor according to preparation example 4 with each other at a weight ratio of 1:3.054. This phosphor mixture was mixed with silicone resin at a weight ratio of 1:20.576 and dispersed into the silicone resin, to obtain a molding resin component. An LED having an emission peak wavelength of 450 nm was employed as a semiconductor light-emitting element 2. FIG. 17 is a graph showing the emission spectrum of semiconductor light-emitting device 1 prepared according to Example 9, with luminous intensities (arbitrary unit) and wavelengths (nm) shown on the axes of ordinates and abscissas respectively. The emission spectrum shown in FIG. 17 was measured with MCPD-2000 (by Otsuka Electronics Co., Ltd.), and adjusted to show a white point around a color temperature of 10,000 K when constituting an image display having a structure according to Example 10 described below.

### Example 10

An image display having the structure shown in FIG. 2 was prepared. Semiconductor light-emitting device 1 according to Example 9 was employed as a backlight source, and a color filter exhibiting the transmittance shown in FIG. 4 was employed.

### Example 11

A semiconductor light-emitting device 1 having the structure shown in FIG. 1 was prepared. As a phosphor dispersed into molding resin 5, a phosphor mixture was obtained by mixing the Mn⁴⁺-activated K₂SiF₆ phosphor according to preparation example 2 and the Mn-activated γ-AlON phosphor according to preparation example 5 with each other at a weight ratio of 1:1.290. This phosphor mixture was mixed with silicone resin at a weight ratio of 1:24.863 and dispersed into the silicone resin, to obtain a molding resin component. An LED having an emission peak wavelength of 450 nm was employed as a semiconductor light-emitting element 2. FIG. 18 is a graph showing the emission spectrum of semiconductor light-emitting device 1 prepared according to Example 11, with luminous intensities (arbitrary unit) and wavelengths (nm) shown on the axes of ordinates and abscissas respectively. The emission spectrum shown in FIG. 18 was measured with MCPD-2000 (by Otsuka Electronics Co., Ltd.), and adjusted to show a white point around a color temperature of 10,000 K when constituting an image display having a structure according to Example 12 described below.

### Example 12

An image display having the structure shown in FIG. 2 was prepared. Semiconductor light-emitting device 1 according to Example 11 was employed as a backlight source, and a color filter exhibiting the transmittance shown in FIG. 4 was employed.

### Comparative Example 1

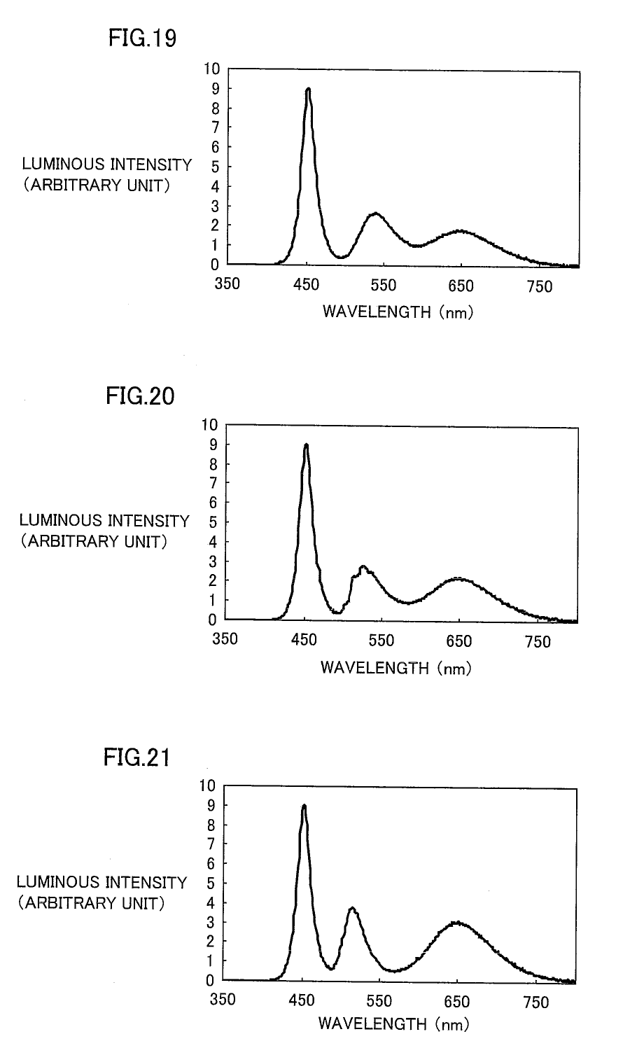

A semiconductor light-emitting device having the structure shown in FIG. 1 was prepared. A phosphor mixture emitting white light obtained by mixing the Eu-activated CaAlSiN₃ phosphor according to comparative preparation example 1 and the Eu-activated β-sialon phosphor according to comparative preparation example 3 with each other at a weight ratio of 1:1.479 was employed as a phosphor dispersed into molding resin. This phosphor mixture was dispersed into silicone resin to be at a weight ratio of 1:16.393, to obtain a molding resin component. An LED having an emission peak wavelength of 450 nm was employed as a semiconductor light-emitting element. FIG. 19 is a graph showing the emission spectrum of the semiconductor light-emitting device prepared according to comparative example 1, with luminous intensities (arbitrary unit) and wavelengths (nm) shown on the axes of ordinates and abscissas respectively. The emission spectrum shown in FIG. 19 was measured with MCPD-2000 (by Otsuka Electronics Co., Ltd.), and adjusted to show a white point around a color temperature of 10,000 K when constituting an image display having a structure according to comparative example 2 described below.

### Comparative Example 2

An image display having the structure shown in FIG. 2 was prepared. The semiconductor light-emitting device according to comparative example 1 was employed as a backlight source, and a color filter exhibiting the transmittance shown in FIG. 4 was employed.

### Comparative Example 3

A semiconductor light-emitting device having the structure shown in FIG. 1 was prepared. A phosphor mixture emitting white light obtained by mixing the Eu-activated CaAlSiN₃ phosphor according to comparative preparation example 1 and the Eu-activated β-sialon phosphor according to comparative preparation example 4 with each other at a weight ratio of 1:1.742 was employed as a phosphor dispersed into molding resin. This phosphor mixture was dispersed into silicone resin to be at a weight ratio of 1:12.048, to obtain a molding resin component. An LED having an emission peak wavelength of 450 nm was employed as a semiconductor light-emitting element. FIG. 20 is a graph showing the emission spectrum of the semiconductor light-emitting device prepared according to comparative example 3, with luminous intensities (arbitrary unit) and wavelengths (nm) shown on the axes of ordinates and abscissas respectively. The emission spectrum shown in FIG. 20 was measured with MCPD-2000 (by Otsuka Electronics Co., Ltd.), and adjusted to show a white point around a color temperature of 10,000 K when constituting an image display having a structure according to comparative example 4 described below.

### Comparative Example 4

An image display having the structure shown in FIG. 2 was prepared. The semiconductor light-emitting device according to comparative example 3 was employed as a backlight source, and a color filter exhibiting the transmittance shown in FIG. 4 was employed.

### Comparative Example 5

A semiconductor light-emitting device having the structure shown in FIG. 1 was prepared. A phosphor mixture emitting white light obtained by mixing the Eu-activated CaAlSiN₃ phosphor according to comparative preparation example 1 and the Mn-activated γ-AlON phosphor according to comparative preparation example 5 with each other at a weight ratio of 1:0.735 was employed as a phosphor dispersed into molding resin. This phosphor mixture was dispersed into silicone resin to be at a weight ratio of 1:13.986, to obtain a molding resin component. An LED having an emission peak wavelength of 450 nm was employed as a semiconductor light-emitting element. FIG. 21 is a graph showing the emission spectrum of the semiconductor light-emitting device prepared according to comparative example 5, with luminous intensities (arbitrary unit) and wavelengths (nm) shown on the axes of ordinates and abscissas respectively. The emission spectrum shown in FIG. 21 was measured with MCPD-2000 (by Otsuka Electronics Co., Ltd.), and adjusted to show a white point around a color temperature of 10,000 K when constituting an image display having a structure according to comparative example 6 described below.

### Comparative Example 6

An image display having the structure shown in FIG. 2 was prepared. The semiconductor light-emitting device according to comparative example 5 was employed as a backlight source, and a color filter exhibiting the transmittance shown in FIG. 4 was employed.

[Results of Evaluation]

Table 1 shows NTSC ratios and chromaticity coordinates of white, red, green and blue points of light components shown on screens of the image displays according to Examples 2, 4, 6, 8, 10 and 12 and comparative examples 2, 4 and 6 on CIE1976 chromaticity diagrams. The red, green and blue points denote chromaticity points on the displays in a case of displaying only light components transmitted through red, green and blue color filters respectively, and the white points denote chromaticity points on the displays in a case of fully opening all color filters. The chromaticity points and the NTSC ratios shown in Table 1 were measured with MCPD-2000 by Otsuka Electronics Co., Ltd.

TABLE 1

| | NTSC | White Point | | Red Point | | Green Point | | Blue Point | |
|---|---|---|---|---|---|---|---|---|---|
| Example | Ratio | u′ | v′ | u′ | v′ | u′ | v′ | u′ | v′ |
| Example 2 | 108.40% | 0.1903 | 0.4399 | 0.515 | 0.515 | 0.103 | 0.574 | 0.169 | 0.173 |
| Example 4 | 111.10% | 0.1902 | 0.4399 | 0.533 | 0.513 | 0.085 | 0.574 | 0.161 | 0.194 |
| Example 6 | 109.40% | 0.1903 | 0.4398 | 0.558 | 0.510 | 0.051 | 0.568 | 0.141 | 0.237 |
| Example 8 | 104.60% | 0.1903 | 0.4399 | 0.506 | 0.517 | 0.087 | 0.573 | 0.161 | 0.192 |
| Example 10 | 102.40% | 0.1902 | 0.4399 | 0.492 | 0.519 | 0.104 | 0.574 | 0.170 | 0.172 |
| Example 12 | 102.60% | 0.1902 | 0.4399 | 0.524 | 0.516 | 0.053 | 0.568 | 0.142 | 0.234 |
| Comparative | 96.20% | 0.1902 | 0.4398 | 0.473 | 0.521 | 0.111 | 0.573 | 0.171 | 0.169 |
| Example 2 | | | | | | | | | |
| Comparative | 97.50% | 0.1902 | 0.4399 | 0.483 | 0.521 | 0.097 | 0.572 | 0.163 | 0.187 |
| Example 4 | | | | | | | | | |
| Comparative | 95.20% | 0.1901 | 0.4399 | 0.496 | 0.520 | 0.074 | 0.567 | 0.146 | 0.224 |
| Example 6 | | | | | | | | | |

It is understood from Table 1 that the green and red points show deeper chromaticness in the image displays according to Examples 2, 4, 6, 8, 10 and 12 as compared with those according to comparative examples 2, 4 and 6. This is because the Mn⁴⁺-activated Mg fluorogermanate phosphor according to preparation example 1 and the Mn⁴⁺-activated K₂SiF₆ phosphor according to preparation example 2 emit light in deeper red and have sharper emission spectral half widths as compared with the Eu-activated CaAlSiN₃ (CASN) phosphor according to comparative preparation example 1. Comparing Examples 2 and 4 and Examples 8 and 10 with each other in particular, it is understood that the image displays according to Examples 4 and 10 show deeper green. This is because the β-sialon phosphor according to preparation example 4 emits deeper green light as compared with the β-sialon phosphor according to preparation example 3.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor light-emitting device comprising a semiconductor light-emitting element emitting excitation light, a green phosphor and a red phosphor, and comprising an Mn⁴⁺-activated phosphor as said red phosphor.

2. The semiconductor light-emitting device according to claim 1, wherein
the emission spectral peak wavelength of said Mn⁴⁺-activated phosphor is at least 625 nm and the emission spectral half width thereof is not more than 30 nm.

3. The semiconductor light-emitting device according to claim 1, wherein
said Mn⁴⁺-activated phosphor is Mn⁴⁺-activated Mg fluorogermanate.

4. The semiconductor light-emitting device according to claim 1, wherein
said Mn⁴⁺-activated phosphor is Mn⁴⁺-activated K₂MF₆ (M=Si, Ge or Ti).

5. The semiconductor light-emitting device according to claim 1, wherein
the emission spectral peak wavelength of said green phosphor is at least 510 nm and not more than 550 nm

6. The semiconductor light-emitting device according to claim 1, wherein
the emission spectral half width of said green phosphor is not more than 55 nm.

7. The semiconductor light-emitting device according to claim 1, wherein
said green phosphor includes Eu-activated β-sialon.

8. The semiconductor light-emitting device according to claim 1, wherein
said green phosphor includes Mn-activated γ-AlON.

9. The semiconductor light-emitting device according to claim 1, wherein
the emission peak wavelength of said semiconductor light-emitting element is 430 to 460 nm.

10. The semiconductor light-emitting device according to claim 9, wherein
the emission peak wavelength of said semiconductor light-emitting element is 440 to 450 nm.

11. An image display comprising the semiconductor light-emitting device according to claim 1 emitting white light as a backlight source.

12. A liquid crystal display comprising the semiconductor light-emitting device according to claim 1 emitting white light as a backlight source.
